(19) United States
(12) Patent Application Publication
(10) Pub. No.: US 2026/0071856 A1
(43) Pub. Date: Mar. 12, 2026

(54) COMPACT ELECTRIC DETONATOR WITH BUILT-IN ELECTROMAGNETIC INTERFERENCE (EMI) FILTER AND METHOD OF ASSEMBLING THE SAME

(71) Applicant: AGENCY FOR DEFENSE DEVELOPMENT, Daejeon (KR)

(72) Inventors: Seung-Gyo JANG, Daejeon (KR); Myung-Geun AHN, Daejeon (KR)

(21) Appl. No.: 19/314,254

(22) Filed: Aug. 29, 2025

(30) Foreign Application Priority Data
Sep. 10, 2024 (KR) 10-2024-0123270

(51) Int. Cl. F42B 3/188; H03H 1/00

(52) U.S. Cl. CPC F42B 3/188; H03H 1/00

(57) ABSTRACT

There is provided a compact electric compressor with a built-in electromagnetic interference (EMI) filter, which can meet the 1W-1A no-fire standard. A compact electric detonator with a built-in EMI filter includes a lead wire composed of a first lead wire and a second lead wire, a cup into which a plug assembly is inserted, wherein the EMI filter through which the first lead wire and the second lead wire pass is installed on the plug assembly, and an adhesive that fixedly bonds an end of the plug assembly and the first lead wire and the second lead wire.

### CROSS REFERENCE TO RELATED APPLICATION

The present application claims priority to Korean Patent Application No. 10-2024-0123270, filed Sep. 10, 2024, the entire contents of which is incorporated herein for all purposes by this reference.

### BACKGROUND OF THE INVENTION

### 1. Field of the Invention

The present invention relates to an electric detonator, and more particularly, to a compact electric detonator with a built-in electromagnetic interference (EMI) filter that complies with the initiator safety regulation of “1W-1A No-Fire (1 watt-1 ampere no-fire)” and a method of assembling the same.

### 2. Description of Related Art

Typically, electric detonators are capable of detonating secondary explosives within milliseconds when receiving an electrical signal.

Historically, in the early stages of development, very sensitive explosives were used to use fast detonators that operate within tens of microseconds for rated current, but since the establishment of the standards for initiators or detonators such as MIL-I-23659 (MIL-DTL-23659), detonators that meet the 1W-1A no-fire standard have been developed.

The 1W-1A no-fire standard is about the sensitivity of the initiator. That is, it is a safety standard to prevent accidental detonation of the detonator by current induced by stray voltage, electrical noise, or electromagnetic interference (EMI).

Most modern guided weapons or satellite launch vehicles need to comply with this standard when applying a detonator. When the detonator was first developed, the focus was on the operational reliability of a detonator, and thus there was no need to meet this standard, but after the establishment of the relevant standard, the standard is considered a basic safety standard for initiators or detonators.

When a detonator for a military industry was first developed, sensitive primary explosives such as lead azide (LA) or lead styphnate (LS) were applied to or adhered to a tungsten bridge wire, and thus could not meet the 1W-1A no-fire standard.

In addition, electric detonators were mainly used as detonators to detonate adjacent explosives, such as warhead fuses, propulsion system ignition safety devices, cutting devices for guided weapon stage separation, etc.

In particular, an EMI filter was installed from the early stages of development to prevent accidental ignition due to EMI. Initially, a powdered iron plug was molded around a lead wire and used. Accordingly, a structure that uses a heating wire connected to a lead wire, like a detonator, has the possibility of accidental ignition in an EMI environment because the lead wire serves as an antenna.

### SUMMARY OF THE INVENTION

The present invention has been proposed to solve the above problems and is directed to providing a compact electric detonator with a built-in electromagnetic interference (EMI) filter that may meet the 1W-1A no-fire standard and a method of assembling the same.

In addition, the present invention is directed to providing a compact electric detonator with a built-in EMI filter that can prevent the possibility of accidental ignition in an EMI environment and a method of assembling the same.

In order to achieve the above objects, according to the present invention, there is provided a compact electric compressor with a built-in electromagnetic interference (EMI) filter, which can meet the 1W-1A no-fire standard.

A compact electric detonator with a built-in EMI filter includes a lead wire composed of a first lead wire and a second lead wire, a cup into which a plug assembly is inserted, wherein the EMI filter through which the first lead wire and the second lead wire pass is installed on the plug assembly, and an adhesive that fixedly bonds an end of the plug assembly and the first lead wire and the second lead wire.

In this case, the plug assembly and the main charge may be horizontally disposed on both internal ends of the cup, and a connecting explosive may be disposed between the plug assembly and the main charge.

In addition, the plug assembly may include a plug housing in which a plurality of holes are formed, the EMI filter inserted into and disposed in a first hole among the plurality of holes, a buffer plate disposed on a lower surface of the EMI filter, a glass bead inserted into and disposed in a third hole among the plurality of holes at a predetermined interval from the buffer plate, and a spacer inserted into and disposed in a fourth hole among the plurality of holes and disposed on a lower surface of the glass bead.

In addition, the glass bead into which the first lead wire and the second lead wire are inserted may melt so that the first lead wire and the second lead wire and the plug housing form a glass-to-metal seal.

In addition, the first lead wire and the second lead wire may protrude and extend from the lower surface of the glass bead so as to be connected to a heating wire.

In addition, the heating wire and ends of the first lead wire and the second lead wire may be connected by spark welding.

In addition, the heating wire 310 may have an electric resistance value of 1 Ω.

In addition, a material of the first lead wire and the second lead wire may be a Ni alloy.

In addition, a powder-type detonating explosive and a spacer powder may be disposed on an inner rear end of the plug assembly.

In addition, the detonating explosive may be filled in a compressed form and disposed within the spacer.

In addition, the detonating explosive may be ZrKClO₄ (zirconium potassium perchlorate (ZPP)).

In addition, at least one of a step of width of each of the plurality of holes may be different.

In addition, the spacer may exhibit ceramic properties and thermal conductivity.

In addition, a material of the EMI filter may be a ferrite core.

In this case, the ferrite core may be a composition using Fe and Zn as main components and adding Ni and Cu.

In addition, portions of one ends of the first lead wire and the second lead wire may be twisted to block external noise.

On the other hand, according to another embodiment of the present invention, there is provided a method of assembling a compact electric detonator with a built-in electromagnetic interference (EMI) filter, which includes an operation (a) of protruding one ends of a first lead wire and a second lead wire beyond a lower surface of a glass bead and extending the first and second lead wires to a bottom surface of the spacer, an operation (b) of connecting a heating wire to the one ends of the first lead wire and the second lead wire, an operation (c) of sequentially inserting a buffer plate and an EMI filter into the other side of the glass bead to complete a plug assembly, an operation (d) of inserting the plug assembly into the cup, and an operation (e) of applying an adhesive to a gap between an end of the plug assembly and the other ends of the first lead wire and the second lead wire and fixedly bonding the plug assembly and the first and second lead wires.

### BRIEF DESCRIPTION OF THE DRAWINGS

FIG. 1 is a cross-sectional view of an electric detonator according to one embodiment of the present invention.

FIG. 2 is a cross-sectional view of a plug assembly shown in FIG. 1.

FIG. 3 is a rear view of the plug assembly shown in FIG. 2.

FIGS. 4A and 4B are a cross-sectional view and a front view of a plug housing shown in FIG. 1.

FIGS. 5A and 5B are a cross-sectional view and a front view of an electromagnetic interference (EMI) filter shown in FIG. 1.

FIGS. 6A and 6B are a cross-sectional view and a front view of a buffer plate shown in FIG. 1.

FIGS. 7A and 7B are a cross-sectional view and a front view of a glass bead shown in FIG. 1.

FIGS. 8A and 8B are a cross-sectional view and a front view of a spacer shown in FIG. 1.

### DETAILED DESCRIPTION OF THE INVENTION

Since the present invention may have various changes and various embodiments, specific embodiments are shown in the accompanying drawings and specifically described in the detail descriptions. However, it should be understood that it is not intended to limit specific embodiments, and it should be understood to include all modifications, equivalents, and substitutes included in the spirit and scope of the present invention.

Like reference numerals have been used for like components throughout the description of each drawing.

Terms such as first, second, etc. may be used to describe various components, but the components should not be limited by the terms. The terms are used only for the purpose of distinguishing one component from another.

For example, a first component may be referred to as a second component, and similarly, the second component may also be referred to as the first component without departing from the scope of the present invention. The term “and/or” includes a combination of a plurality of related listed items or any of the plurality of related listed items.

Unless defined otherwise, all terms used herein, including technical or scientific terms, have the same meaning as commonly understood by those of ordinary skill in the art to which the present invention pertains.

The terms defined in a generally used dictionary should be construed as meanings that match with the meanings of the terms from the context of the related technology and are not construed as an ideal or excessively formal meaning unless clearly defined in this application.

Hereinafter, a compact electric detonator with a built-in electromagnetic interference (EMI) filter and a method of assembling the same according to one embodiment of the present invention will be described in detail with reference to the accompanying drawings.

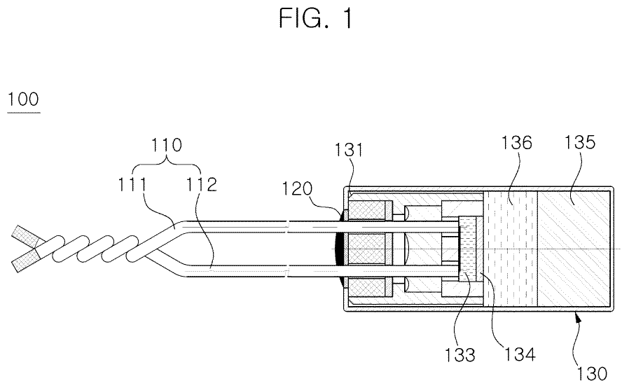

FIG. 1 is a cross-sectional view of an electric detonator 100 according to one embodiment of the present invention. Referring to FIG. 1, the electric detonator 100 may include a lead wire 110, a cup 130 to which the lead wire 110 is connected, an adhesive 120 that bonds the lead wire 110 to the cup 130.

The lead wire 110 is composed of a first lead wire 111 and a second lead wire 112, and a portion of a left end (i.e., one end) is twisted together in the drawing. This is an electrically shorted state to prevent external noise. Of course, at a right end (i.e., the other end), the first lead wire 111 and the second lead wire 112 are disposed in parallel at a predetermined interval.

A plug assembly 131, a detonating explosive 133, a spacer powder 134, a main charge 135, a connecting explosive 136, and the like are disposed horizontally inside the cup 130. The plug assembly 131 and the main charge 135 are disposed horizontally on both internal ends of the cup 130, and the connecting explosive 136 is disposed between the plug assembly 131 and the main charge 135.

An EMI filter is disposed on a front end of the plug assembly 131, and the detonating explosive 133 and the spacer powder 134 are disposed on a rear end thereof. The detonating explosive 133 is connected to the other ends of the first lead wire 111 and the second lead wire 112. The spacer powder 134 is formed of boron nitride (BN), which is the same material as a spacer 250. By using the spacer powder, the detonating explosive is surrounded by a material called BN.

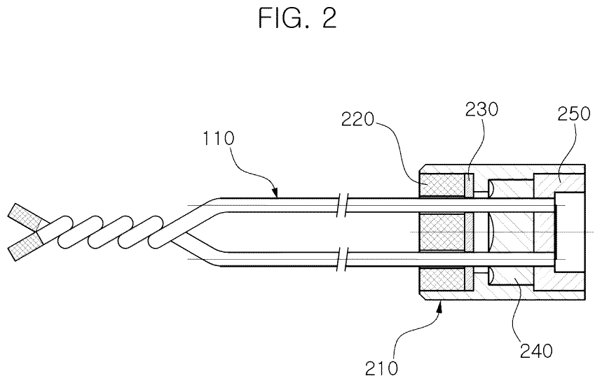

FIG. 2 is a cross-sectional view of the plug assembly 131 shown in FIG. 1. Referring to FIG. 2, the plug assembly 131 includes a plug housing 210 that forms an exterior and has a plurality of holes with steps formed therein, an EMI filter 220 disposed on an internal front end of the plug housing 210, a buffer plate 230 disposed on a lower surface of the EMI filter 220, a glass bead 240 disposed at a predetermined interval from the buffer plate 230, a spacer 250 disposed on a lower surface of the glass bead 240, etc.

In the plug assembly 131, when the glass bead 240 into which first and second lead wires 111 and 112 are inserted is inserted into the plug housing 210 and is heated at high temperature, the glass bead 240 melts so that the lead wires 111 and 112 and the plug housing form a glass-to-metal seal.

In this way, the lead wires 111 and 112 can be perfectly insulated from the plug housing 210 and at the same time, can maintain airtightness. Since explosives are sensitive to moisture, such a glass-to-metal sealing technology is required to prevent external moisture from penetrating the detonating explosive 133.

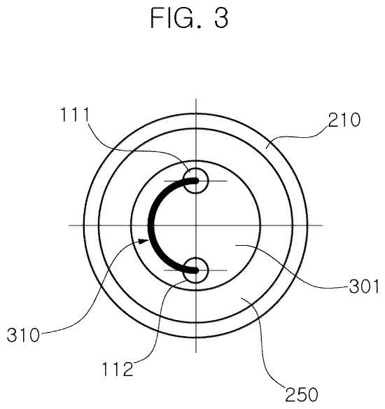

FIG. 3 is a rear view of the plug assembly 131 shown in FIG. 2. Referring to FIG. 3, the lead wires 111 and 112 may be formed of a Ni alloy. One ends of the lead wires 111 and 112 are formed to protrude slightly beyond a lower surface of the glass bead 240 and extend to a bottom surface 301 of the spacer 250, and a heating wire 310 is connected to both ends of the lead wires 111 and 112 by spark welding on the bottom surface 301 of the spacer 250. On the other side of the glass bead 240, the buffer plate 230 and the EMI filter 220 are sequentially inserted to complete the plug assembly 131. Stainless steel (STS) 304 fine wire may be used as the heating wire 310.

The 1W-1A no-fire standard states that, when an electrical resistance value of the heating wire 310 is 1 Ω, the detonator should not initiate even when a current of 1 A is applied for 5 minutes. The use of pyrotechnics, which is an insensitive explosive, can meet this standard.

To this end, in one embodiment of the present invention, an insensitive explosive ZrKClO₄ (zirconium potassium perchlorate (ZPP)) is used as the detonating explosive 133.

In particular, the powder-type detonating explosive 133 is filled in a compressed form and disposed within the spacer 250. That is, since the spacer 250 has a cylindrical shape with the bottom surface 301, the detonating explosive 133 is pressed and filled within the space 250. Accordingly, since the heating wire 310 comes in close contact with the detonating explosive 133, the heat generated from the heating wire 310 is directly transferred to the detonating explosive 133, and the detonating explosive 133 is combusted when reaching spontaneous ignition temperature. Subsequently, the adjacent connecting explosive 136 and the main charge 135 are detonated, causing the detonator to operate.

The 1W-1A no-fire standard stating that, when an electrical resistance value of the heating wire 310 is 1 Ω, the detonator should not initiate even when a current of 1 A is applied for 5 minutes is closely related to the thermal characteristics of the spacer in which the ZPP is filled. When the current of 1 A is supplied to the heating wire, a lot of heat is generated, and the heat is transferred to the ZPP 133 and then to the spacer 250.

Subsequently, the heat is eventually transferred to the plug housing 210. In this case, the spacer 250 can meet the 1W-1A no-fire standard using a material with very high thermal conductivity. At the same time, this spacer needs to have good electrical insulation. Usually, a material with high specific resistance and good processability is selected.

High specific resistance prevents accidental ignition due to static electricity, and good processability is required to facilitate manufacturing. In one embodiment of the present invention, BN or the like is used to meet such characteristics. BN has properties similar to ceramics in terms of electrical resistance and exhibits thermal conductivity similar to metal.

When using a heating wire with an electric resistance value of about 1 Ω and using ZPP as a detonator, BN is a material that meets the 1W-1A no-fire safety standard. In terms of heat conduction, the spacer needs to be in close contact with the plug housing, and the plug housing should be in close contact with the cup as much as possible, which is advantageous and can meet the 1W-1A no-fire safety standard.

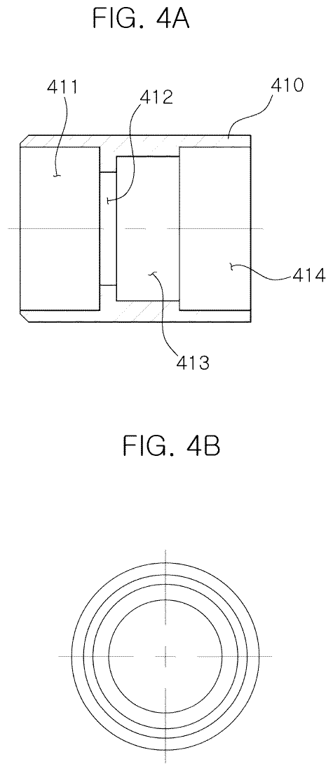

FIGS. 4A and 4B are a cross-sectional view and a front view of the plug housing 210 shown in FIG. 1, respectively. Referring to FIG. 4A, first to fourth holes 411, 412, 413, and 414 having a step are formed inside a body 410.

The EMI filter 220 is inserted into and disposed in the first hole 411, and the buffer plate 230 is disposed on the lower surface of the EMI filter 220.

The second hole 412 stepped from the first hole 411 is formed. That is, the second hole 412 having a smaller diameter than the first hole 411 is formed. Of course, a width of the second hole 412 is narrower than a width of the first hole 411. The third hole 413 stepped from the first hole 411 is formed.

A diameter of the third hole 413 is larger than a diameter of the second hole 412 but smaller than a diameter of the first hole 411. In addition, a width of the third hole 413 is larger than the width of the second hole 412 but smaller than the width of the first hole 411.

The fourth hole 414 stepped from the third hole 413 is formed. That is, the fourth hole 414 having a larger diameter than the third hole 413 is formed. Of course, the diameter of the fourth hole 414 is equal to the diameter of the first hole 411. In addition, a width of the fourth hole 414 is larger than the width of the third hole 413 but smaller than the width of the first hole 411.

A step closest to the lead wires 111 and 112 among the steps is called a spark gap and serves to allow electrostatic signals coming through the lead wires 111 and 112 to flow toward the housing through this spark gap.

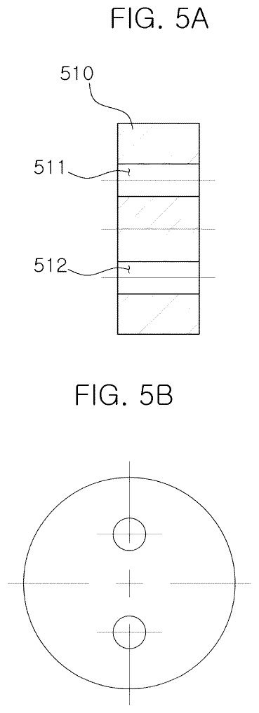

FIGS. 5A and 5B are a cross-sectional view and a front view of the EMI filter 220 shown in FIG. 1, respectively. Referring to the cross-sectional view of FIG. 5, the EMI filter 220 has through holes 511 and 512 formed in the body 510 for inserting the lead wires 111 and 112. A ferrite core may be used as a material of the body 510. The shape in which the through holes 511 and 512 may be molded and inserted into the lead wires 111 and 112 is designed, thereby increasing detonator manufacturing efficiency.

As in one embodiment of the present invention, the structure in which the heating wire 310 is connected to the lead wires 111 and 112 serves as an antenna has the possibility that the lead wires may serve as an antenna and cause accidental ignition in an EMI environment. In order to prevent this, when a ferrite core is inserted around the lead wires, a radio frequency (RF) signal induced in the lead wires can be significantly reduced. An attenuation rate may vary depending on a component of the ferrite core, and in the present invention, a composition using Fe and Zn as main components and adding Ni and Cu may be used.

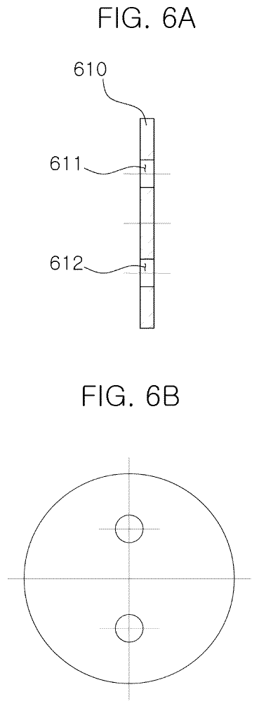

FIGS. 6A and 6B are a cross-sectional view and a front view of the buffer plate 230 shown in FIG. 1, respectively. Referring to FIG. 6, two through holes 611 and 612 are formed in a body 610 so that the lead wires 111 and 112 are inserted into and passes through the two through holes, respectively. The material of the buffer plate 230 may be a silicon rubber or the like.

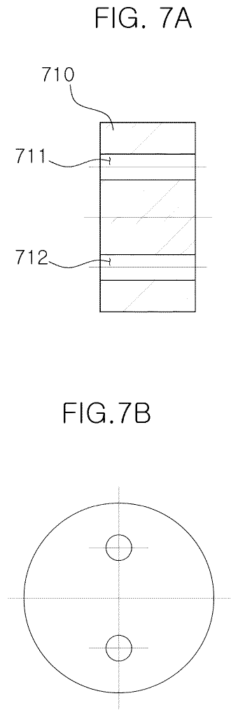

FIGS. 7A and 7B are a cross-sectional view and a front view of the glass bead 240 shown in FIG. 1, respectively. Referring to FIG. 7, two through holes 711 and 712 are formed in a body 710 so that the lead wires 111 and 112 are inserted into and pass through the two through holes, respectively.

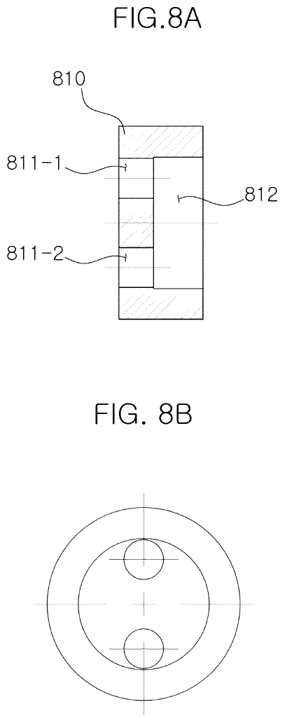

FIGS. 8A and 8B are a cross-sectional view and a front view of the spacer 250 shown in FIG. 1, respectively. Referring to FIG. 8, two through holes 811 and 812 and a filling space 812 to compress and fill the detonating explosive 133 are formed so that the lead wires 111 and 112 are inserted into and pass through the two through holes, respectively.

The electric detonator is more applicable as it becomes smaller. In order to serve as a detonator that detonates the secondary explosive, the amounts of the detonating explosive, the connecting explosive, and the main charge are optimally designed, and accordingly, the spacer, the glass bead, the buffer plate, and the EMI filter may all be assembled within a cup diameter of 5 mm.

In the plug assembly 131 assembled in this way, final assembly is prepared by charging 10 mg of ZPP (ZrKClO₄) at a pressure of 10,000 psi, and then charging 5 mg of BN at a pressure of 5,000 psi. By charging BN on ZPP, insulation resistance between ZPP and the housing can be increased. The plug housing may be manufactured by processing STS 303.

Separately, the cup 130 for charging high explosives is processed by using a material such as stainless steel 305 or the like, and first, the detonating explosive 133 is charged with 52 mg of RDX at a pressure of 10,000 psi, and then 120 mg of the connecting explosive LA is charged at a pressure of 15,000 psi.

Since the charging pressure of such high explosives is related to a charging density and also related to detonation performance, the explosive needs to be charged at a specified pressure.

The plug assembly and the cup charged with explosives are coupled as shown in FIG. 1, and the end of the cup is crimped so that the BN powder portion at the end of the plug assembly is sufficiently in close contact with the connecting explosive. Thereafter, an epoxy adhesive is sufficiently applied between the end of the plug assembly and the lead wires to maintain airtightness, thereby completing an electric detonator.

According to the present invention, silver resistivity can prevent accidental ignition due to static electricity and provide good processability, thereby meeting the 1W-1A no-fire standard.

In addition, according to the present disclosure, it is possible to prevent the possibility of accidental ignition in an EMI environment.

What is claimed is:

1. A compact electric detonator with a built-in electromagnetic interference (EMI) filter, comprising:
a lead wire composed of a first lead wire and a second lead wire;
a cup into which a plug assembly is inserted, wherein the EMI filter through which the first lead wire and the second lead wire pass is installed on the plug assembly; and
an adhesive that fixedly bonds an end of the plug assembly and the first lead wire and the second lead wire.

2. The compact electric detonator of claim 1, wherein the plug assembly and the main charge are horizontally disposed on both internal ends of the cup, and a connecting explosive is disposed between the plug assembly and the main charge.

3. The compact electric detonator of claim 2, wherein the plug assembly includes:
a plug housing in which a plurality of holes are formed;
the EMI filter inserted into and disposed in a first hole among the plurality of holes;
a buffer plate disposed on a lower surface of the EMI filter;
a glass bead inserted into and disposed in a third hole among the plurality of holes at a predetermined interval from the buffer plate; and
a spacer inserted into and disposed in a fourth hole among the plurality of holes and disposed on a lower surface of the glass bead.

4. The compact electric detonator of claim 3, wherein the glass bead into which the first lead wire and the second lead wire are inserted melts so that the first lead wire and the second lead wire and the plug housing form a glass-to-metal seal.

5. The compact electric detonator of claim 3, wherein the first lead wire and the second lead wire protrude and extend from the lower surface of the glass bead so as to be connected to a heating wire.

6. The compact electric detonator of claim 5, wherein the heating wire and ends of the first lead wire and the second lead wire are connected by spark welding.

7. The compact electric detonator of claim 5, wherein the heating wire 310 has an electric resistance value of 1 Ω.

8. The compact electric detonator of claim 3, wherein a material of the first lead wire and the second lead wire is a Ni alloy.

9. The compact electric detonator of claim 3, wherein a powder-type detonating explosive and a spacer powder are disposed on an inner rear end of the plug assembly.

10. The compact electric detonator of claim 9, wherein the detonating explosive is filled in a compressed form and disposed within the spacer.

11. The compact electric detonator of claim 9, wherein the detonating explosive is ZrKClO₄ (zirconium potassium perchlorate (ZPP)).

12. The compact electric detonator of claim 3, wherein at least one of a step of width of each of the plurality of holes is different.

13. The compact electric detonator of claim 3, wherein the spacer exhibits ceramic properties and thermal conductivity.

14. The compact electric detonator of claim 1, wherein a material of the EMI filter is a ferrite core, and the ferrite core is a composition using Fe and Zn as main components and adding Ni and Cu.

15. The compact electric detonator of claim 1, wherein portions of one ends of the first lead wire and the second lead wire are twisted to block external noise.

16. A method of assembling a compact electric detonator with a built-in electromagnetic interference (EMI) filter, the method comprising:
protruding one ends of a first lead wire and a second lead wire beyond a lower surface of a glass bead and extending the first and second lead wires to a bottom surface of the spacer;
connecting a heating wire to the one ends of the first lead wire and the second lead wire;
sequentially inserting a buffer plate and an EMI filter into the other side of the glass bead to complete a plug assembly;
inserting the plug assembly into the cup; and
applying an adhesive to a gap between an end of the plug assembly and the other ends of the first lead wire and the second lead wire and fixedly bonding the plug assembly and the first and second lead wires.
